(19) United States
(12) Patent Application Publication
(10) Pub. No.: US 2010/0283070 A1
(43) Pub. Date: Nov. 11, 2010

(54) Nitride semiconductor light emitting device and method of manufacturing the same

(75) Inventors: Sun Woon Kim, Seoul (KR); Dong Joon Kim, Suwon (KR); Dong Ju Lee, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/007,497

(22) Filed: Jan. 11, 2008

(30) Foreign Application Priority Data
Feb. 12, 2007 (KR) 10-2007-0014450

(51) Int. Cl. H01L 33/10; H01L 33/26

(52) U.S. Cl. 257/98; 438/29; 257/103; 257/E33.067; 257/E33.055; 257/E33.013

(57) ABSTRACT

There are provided a nitride semiconductor light emitting device having improved light extraction efficiency and a method of manufacturing the same. A nitride semiconductor light emitting device according to an aspect of the invention includes a light emitting lamination including first and second conductivity type nitride semiconductors and an active layer formed therebetween, first and second electrode pads electrically connected to the first and second conductivity nitride semiconductor layers, respectively, a plurality of patterns formed below the second electrode pad and having a depth reaching at least part of the first conductivity type nitride semiconductor layer, and an insulating film formed at an internal surface of the plurality of patterns to electrically insulate a region of a light emitting lamination, which is exposed through the plurality of patterns, from the second electrode pad.

### CROSS-REFERENCE TO RELATED APPLICATIONS

This application claims the priority of Korean Patent Application No. 2007-14450 filed on Feb. 12, 2007, in the Korean Intellectual Property Office, the disclosure of which is incorporated herein by reference.

### BACKGROUND OF THE INVENTION

1. Field of the Invention

The present invention relates to a nitride semiconductor light emitting device and a method of manufacturing the same, and more particularly, to a nitride semiconductor light emitting device that improves light extraction efficiency by using a local pattern structure and a method of manufacturing the same.

2. Description of the Related Art

In general, nitride semiconductors have been widely used in green or blue light emitting diodes (LEDs) that are provided as light sources in full color displays, image scanners, various kinds of signal systems, and optical communication devices. The LEDs generate light in active layers by recombination of electrons and holes and emit light.

Luminous efficiency of a nitride semiconductor light emitting device is determined by internal quantum efficiency and light extraction efficiency (also called “external quantum efficiency”). Particularly, the light extraction efficiency is greatly affected by optical factors of the light emitting device, that is, a refractive index of individual structures and/or flatness of an interface.

However, the nitride semiconductor light emitting device has inherent limitations in terms of light extraction efficiency.

Since a nitride semiconductor layer that forms the light emitting device has a higher refractive index than the air or a substrate, the critical angle that determines the angle of incidence at which light can be emitted is reduced. As a result, most of the light generated from the active layer undergoes total internal reflection. Light propagates along an undesired direction or optical loss occurs during total internal reflection to thereby reduce the light extraction efficiency. More specifically, in the nitride semiconductor light emitting device, since GaN has a refractive index of 2.4, when an emitting angle of light generated in the active layer is larger than the critical angle of 23.6° at the GaN/air interface, the light undergoes total internal reflection. During total internal reflection, the light moves in a lateral direction and is lost, or the light is not emitted along a desired direction. Therefore, the light emitting device only has a light extraction efficiency of 13%. Similarly, since a sapphire substrate has a refractive index of 1.78, light extraction efficiency is low at the sapphire/air interface.

Further, electrode pads connected to an external device by wire absorb light generated from the active layer to thereby deteriorate light extraction efficiency.

As such, the nitride semiconductor emitting device reduces light extraction efficiency due to optical characteristics according to the refractive index of the nitride semiconductor layer, and necessary structures for providing external connections. Therefore, there is a need for a new method of improving light extraction efficiency.

### SUMMARY OF THE INVENTION

An aspect of the present invention provides a nitride semiconductor light emitting device that improves light extraction efficiency by changing a semiconductor structure located at an electrode pad region.

An aspect of the present invention also provides a method of manufacturing the nitride semiconductor light emitting device.

According to an aspect of the present invention, there is provided a nitride semiconductor light emitting device including: a light emitting lamination including first and second conductivity type nitride semiconductors and an active layer formed therebetween; first and second electrode pads electrically connected to the first and second conductivity nitride semiconductor layers, respectively; a plurality of patterns formed below the second electrode pad and having a depth reaching at least part of the first conductivity type nitride semiconductor layer; and an insulating film formed at an internal surface of the plurality of patterns to electrically insulate a region of a light emitting lamination, which is exposed through the plurality of patterns, from the second electrode pad.

Each of the plurality of patterns may have inclined side surfaces narrowing with depth.

The light emitting lamination may have a mesa-etched structure to expose a region of the first conductivity type nitride semiconductor layer, and the first electrode pad may be formed at the exposed region. The plurality of patterns may have the same depth as the mesa etching depth.

The nitride semiconductor light emitting device may further include a transparent electrode layer formed at an upper surface of the second conductivity type nitride semiconductor layer.

Each of the first and second electrode pads may be a single layer or a multilayer formed of a material of Ti, Cr, Al, Cu, Au, W, and alloys thereof.

Each of the plurality of patterns may have a width of 5 to 50 μl.

The insulating film may be an oxide or a nitride containing an element of Si, Zr, Ta, Ti, In, Sn, Mg, and Al.

The nitride semiconductor light emitting device may further include a high reflective metal layer formed on the insulating film located at least the plurality of patterns. The high reflective metal layer may include at least one of Al, Ag, Rh, Ru, Pt, Pd, and alloys thereof.

According to another aspect of the present invention, there is provided a method of manufacturing a nitride semiconductor light emitting device, the method including: preparing a light emitting lamination including first and second conductivity type nitride semiconductor layers and an active layer formed therebetween; forming a plurality of patterns in a region of the second conductivity type semiconductor layer, where a second electrode pad will be formed, the plurality of patterns having a depth reaching at least part of the first conductivity type nitride semiconductor layer; forming an insulating film at an internal surface of the plurality of patterns; and forming first and second electrode pads electrically connected to the first and second conductivity type nitride semiconductor layers.

The method may further include mesa etching the light emitting lamination to expose a region of the first conductivity type semiconductor layer, where a first electrode pad will be formed. The forming a plurality of patterns may be performed simultaneously with the mesa etching.

The method may further forming a high reflective metal layer on the insulating film located at least the plurality of patterns between the forming an insulating film and the forming a second electrode pattern.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a side cross-sectional view illustrating a nitride semiconductor light emitting device according to one exemplary embodiment of the present invention.

FIG. 2 is a side cross-sectional view illustrating a nitride semiconductor light emitting device according to another exemplary embodiment of the present invention.

FIGS. 3A to 3D are procedural cross-sectional views illustrating a method of manufacturing a nitride semiconductor light emitting device according to still another exemplary embodiment of the present invention.

### DETAILED DESCRIPTION OF THE PREFERRED EMBODIMENT

Exemplary embodiments of the present invention will now be described in detail with reference to the accompanying drawings.

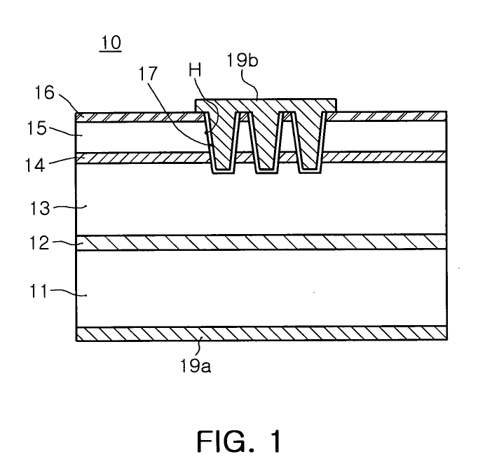

FIG. 1 is a side cross-sectional view illustrating a nitride semiconductor light emitting device according to one exemplary embodiment of the invention.

Referring to FIG. 1, a vertical nitride semiconductor light emitting device 10 is shown. The nitride semiconductor light emitting device 10 includes a light emitting lamination that has first and second conductivity type nitride semiconductor layers 13 and 15 and an active layer 14 formed therebetween. The light emitting lamination is formed at an upper surface of a conductive substrate 11 on which a buffer layer 12 is formed. The conductive substrate 11 may be a GaN substrate or a Si substrate.

The nitride semiconductor light emitting device 10 includes first and second electrode pads 19a and 19b that are electrically connected to the first and second conductivity type nitride semiconductor layers 13 and 15, respectively. In this embodiment, the first electrode pad 19a is formed at a lower surface of the conductive substrate 11. The second electrode pad 19b is formed at a transparent electrode layer 16 that is formed on the second conductivity type nitride semiconductor layer 15. The first and second electrode pads 19a and 19b are connected to an external device (not shown) by wire bonding or direct mounting. Each of the first and second electrode pads 19a and 19b may be a single layer or a multilayer that is formed of a material selected from a group consisting of Ti, Cr, Al, Cu, Au, W, and alloys thereof.

In this embodiment, a plurality of patterns H are formed in the light emitting lamination located below the second electrode pad 19b. The plurality of patterns H have a depth ranging from the second conductivity type nitride semiconductor layer 15 to at least part of the first conductivity type nitride semiconductor layer 13 through the active layer 14. During a selective etching process of forming the patterns H, each of the patterns H may be formed according to a predetermined crystal surface of a nitride single crystal.

Therefore, each of the plurality of patterns H may have inclined side surfaces while the patterns H narrow with depth. In this embodiment, each of the plurality of patterns H may have a top width of 5 to 50 μM.

An insulating film 17 is formed on an internal surface of the plurality of patterns H. The insulating film 17 electrically insulates portions of the first conductivity type nitride semiconductor layer 13 and the active layer 14, which are exposed through the patterns H, from the second electrode pad 19b. The insulating film 17 may be an oxide or a nitride containing an element selected from a group consisting of Si, Zr, Ta, Ti, In, Sn, Mg, and Al.

As such, in the nitride semiconductor light emitting device 10 according to the embodiment of the invention, since the plurality of patterns H are formed below the second electrode pad 19b and are filled with metal, it is possible to variously change a path of light generated from the active layer 14. Therefore, as described above, the light whose path is changed is more likely to be incident on the interface at an angle within the critical angle range that allows light extraction, which is limited by a difference in refractive index between the nitride single crystal and the air. As a result, light extraction efficiency of the light emitting device 10 can be improved.

Further, since the insulating film 17 is formed on the patterns H that are formed by partial etching, different portions of the second electrode pad 19b are in direct contact with the transparent electrode layer 16. Therefore, since the current flows through the distributed portions of the second electrode pad 19b, it is possible to prevent formation of areas of high current density. Therefore, current spreading can be expected.

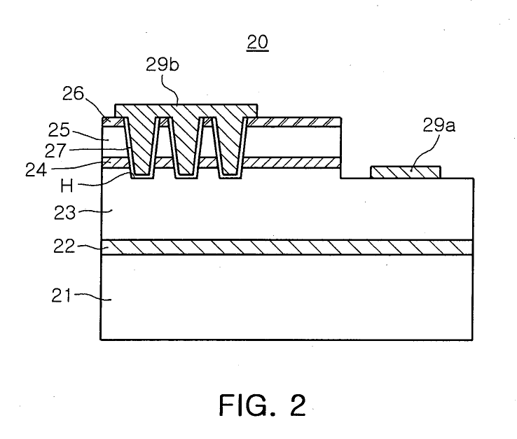

FIG. 2 is a side cross-sectional view illustrating a nitride semiconductor light emitting device according to another exemplary embodiment of the present invention.

Referring to FIG. 2, unlike to the embodiment shown in FIG. 1, a horizontal nitride semiconductor light emitting device 20 has two electrodes disposed in the same plane direction.

The nitride semiconductor light emitting device 20 includes a light emitting lamination that has first and second conductivity type nitride semiconductor layers 23 and 25 and an active layer 24 formed therebetween. The light emitting lamination is formed at an upper surface of a substrate 21 on which the buffer layer 22 is formed. The substrate 21 may be an insulating substrate such as a sapphire substrate.

The nitride semiconductor light emitting device 20 includes first and second electrode pads 29a and 29b that are electrically connected to the first and second conductivity type nitride semiconductor layers 23 and 25, respectively. In this embodiment, the second electrode pad 29b is formed at a transparent electrode layer 26 that is formed on the second conductivity type nitride semiconductor layer 25. However, since the insulating substrate is provided, the first electrode pad 29a is directly formed on a region of the first conductivity type nitride semiconductor layer 23 that is exposed by an additional mesa etching process. Each of the first and second electrode pads 29a and 29b may be a single layer or a multilayer that is formed of a material selected from a group consisting of Ti, Cr, Al, Cu, Au, W, and alloys thereof.

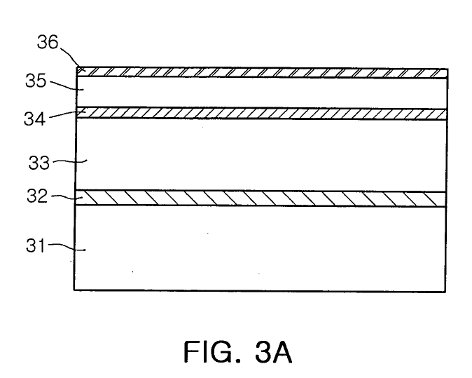

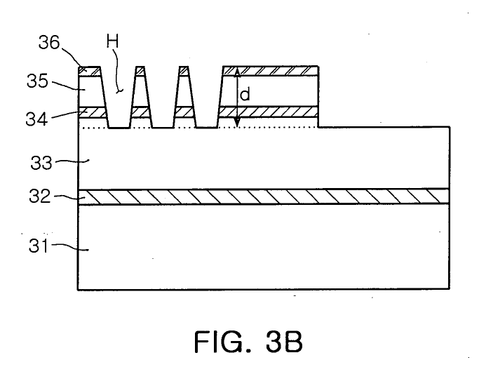

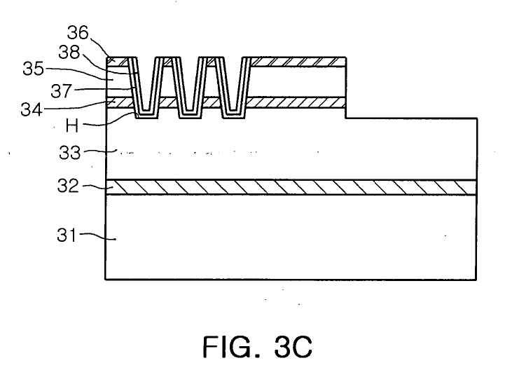

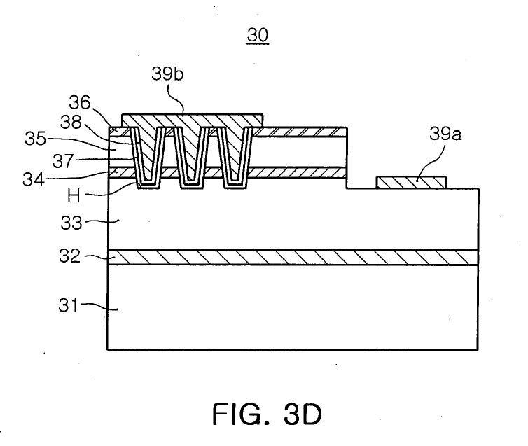

Further, like the embodiment shown in FIG. 1, a plurality of patterns H are formed in the light emitting lamination located below the second electrode pad 29b. Each of the plurality of patterns H has a depth ranging from the second conductivity type nitride semiconductor layer 25 to the second conductivity type nitride semiconductor layer 23 through the active layer 24. In this embodiment, preferably, a process of forming the patterns H is performed together with the mesa etching process of forming the region where the first electrode pad 29a is formed. The process of forming the patterns H can be easily performed simultaneously with the general mesa etching process by changing a mask to be used during mesa etching without requiring an addition process. In this case, as shown in FIG. 2, the patterns H have the almost same depth as the mesa etching depth. This will be described in more detail with reference to FIG. 3B.

An insulating film 27 is formed on an internal surface of the plurality of patterns H. The insulating film 27 electrically insulates portions of the first conductivity type nitride semiconductor layer 23 and the active layer 24, which are exposed through the patterns H, from the second electrode pad 29b. The insulating film 27 may be an oxide or a nitride that contains an element selected from a group consisting of Si, Zr, Ta, Ti, In, Sn, Mg, and Al.

As such, in the nitride semiconductor light emitting device 20 according to the embodiment of the invention, the plurality of patterns H that are provided below the second electrode pad 29b allow light generated from the active layer 24 to have various paths in the light emitting lamination, thereby increasing light extraction efficiency. As a result, light extraction efficiency of the light emitting device 20 can be improved. Since a current is selectively conducted through the distributed connecting regions of the second electrode pad 29b, current spreading may be expected.

The plurality of patterns that are used in the embodiment of the invention causes a change in optical path in the light emitting lamination to thereby improve light extraction efficiency. In order to prevent optical absorption caused by electrode pad materials and improve the effect of changing an optical path, it is preferable that a high reflective metal layer be further formed on the insulating film located on the plurality of patterns. This will be described in more detail on the basis of a manufacturing method shown in FIGS. 3A to 3D.

FIGS. 3A to 3D are procedural cross-sectional views illustrating a method of manufacturing a nitride semiconductor light emitting device according to still another exemplary embodiment of the present invention.

According to the manufacturing method according to this embodiment, first, a light emitting lamination that includes first and second conductivity type nitride semiconductor layers 33 and 35 and an active layer 34 formed therebetween is prepared. During this process, as shown in FIG. 3A, a buffer layer 32 for growing a nitride single crystal, such as a low-temperature nitride forming layer, is formed on a sapphire substrate 31, and then a process of growing the nitride single crystal for the light emitting lamination is performed. The nitride single crystal growing process may be performed by known growth processes, such as MOCVD and MBE. A transparent electrode layer 36 may be further formed on the second conductivity type semiconductor layer 35 so as to improve current spreading effect.

Then, a plurality of patterns H having a depth reaching at least part of the first conductivity type semiconductor layer 33 are formed in a region of the second conductivity type semiconductor layer 35, where a second electrode pad (reference numeral 39b of FIG. 3D) is formed. In this embodiment, when mesa etching needs to be performed to ensure a region where a first electrode (reference numeral 39a of FIG. 3D), as shown in FIG. 3B, the mesa etching can be performed simultaneously with an etching process of forming the patterns H. Further, as described above, each of the patterns H used in this embodiment of the invention has the depth d extending to at least part of the first conductivity type semiconductor layer 33 through the active layer 34 in order to more effectively change an optical path in the light emitting lamination. Therefore, the process of forming the patterns can be performed together with the mesa etching process of exposing the first conductivity type semiconductor layer 33. The etching process of forming the patterns may not be added.

An internal surface of the patterns H that are obtained according to the etching process may have inclined surfaces that are defined by a crystal surface of the nitride single crystal. The inclined surfaces allow the optical path to be effectively changed.

As shown in FIG. 3C, an insulating film 37 is formed on the internal surface of the plurality of patterns H so that portions of the first conductivity type semiconductor layer 33 and the active layer 34 that are exposed through the patterns H are not connected to the second electrode pad 39b to be formed in a subsequent process. The insulating film 37 is not limited thereto, but the insulating film 37 may be an oxide or a nitride that contains an element selected from a group consisting of Si, Zr, Ta, Ti, In, Sn, Mg, and Al. Preferably, as shown in FIG. 3C, after the process of forming the insulating film 37, a high reflective metal layer 38 may be further formed on the insulating film 37. The high reflective metal layer 38 prevents optical absorption caused by electrode pad materials to be formed in a subsequent process to thereby improve luminous efficiency and light extraction efficiency. The high reflective metal layer 38 is not limited thereto, but the high reflective metal layer 38 may contain at least one selected from a group consisting of Al, Ag, Rh, Ru, Pt, Pd, and alloys thereof.

Finally, as shown in FIG. 3D, the first and second electrode pads 39a and 39b are formed to be electrically connected to the first and second conductivity type nitride semiconductor layers 33 and 35, respectively. Here, the second electrode pad 39b may fill the inside of the patterns H. The first and second electrode pads 39a and 39b are not limited thereto. However, each of the first and second electrode pads 39a and 39b may be a single layer or a multilayer that is formed of a material selected from a group consisting of Ti, Cr, Al, Cu, Au, W, and alloys thereof. As described above, the insulating film 37 limits the current conduction to a region of the second electrode pad 39b that is in contact with the patterns H, while the current is conducted through a region of the second electrode pad 39b that is indirect contact with the transparent electrode layer 36, such that a current spreading effect may also be achieved.

The nitride semiconductor light emitting device 30, shown in FIG. 3D, prevents optical absorption caused by the second electrode pad 39b to reduce optical loss and significantly improve the effect of changing the optical path by a high reflective surface provided by the high reflective metal layer 38.

As set forth above, according to exemplary embodiments of the invention, patterns are formed at a nitride single crystal region located below an electrode pad to change an optical path, thereby improving light extraction efficiency. In particular, since inclined surfaces are formed according to a crystal surface of the nitride crystal surface, an effect of improving extraction efficiency by changing an optical path can be increased. Further, according to exemplary embodiments of the invention, a high reflective metal layer is provided at an internal surface of the patterns to prevent optical loss by electrode pad materials and effectively change an optical path, thereby significantly improving light extraction efficiency.

While the present invention has been shown and described in connection with the exemplary embodiments, it will be apparent to those skilled in the art that modifications and variations can be made without departing from the spirit and scope of the invention as defined by the appended claims.

What is claimed is:

1. A nitride semiconductor light emitting device comprising:
a light emitting lamination including first and second conductivity type nitride semiconductors and an active layer formed therebetween;
first and second electrode pads electrically connected to the first and second conductivity nitride semiconductor layers, respectively;
a plurality of patterns formed below the second electrode pad and having a depth reaching at least part of the first conductivity type nitride semiconductor layer; and
an insulating film formed at an internal surface of the plurality of patterns to electrically insulate a region of a light emitting lamination, which is exposed through the plurality of patterns, from the second electrode pad.

2. The nitride semiconductor light emitting device of claim 1, wherein each of the plurality of patterns has inclined side surfaces narrowing with depth.

3. The nitride semiconductor light emitting device of claim 1, wherein the light emitting lamination has a mesa-etched structure to expose a region of the first conductivity type nitride semiconductor layer, and the first electrode pad is formed at the exposed region.

4. The nitride semiconductor light emitting device of claim 3, wherein the plurality of patterns have the same depth as the mesa etching depth.

5. The nitride semiconductor light emitting device of claim 1, further comprising:
a transparent electrode layer formed at an upper surface of the second conductivity type nitride semiconductor layer.

6. The nitride semiconductor light emitting device of claim 1, wherein each of the first and second electrode pads is a single layer or a multilayer formed of a material selected from a group of consisting of Ti, Cr, Al, Cu, Au, W, and alloys thereof.

7. The nitride semiconductor light emitting device of claim 1, wherein each of the plurality of patterns has a width of 5 to 50 μm.

8. The nitride semiconductor light emitting device of claim 1, wherein the insulating film is an oxide or a nitride containing an element selected from a group consisting of Si, Zr, Ta, Ti, In, Sn, Mg, and Al.

9. The nitride semiconductor light emitting device of claim 1, further comprising:
a high reflective metal layer formed on the insulating film located at least the plurality of patterns.

10. The nitride semiconductor light emitting device of claim 9, wherein the high reflective metal layer comprises at least one selected from a group consisting of Al, Ag, Rh, Ru, Pt, Pd, and alloys thereof.

11. A method of manufacturing a nitride semiconductor light emitting device, the method comprising:
preparing a light emitting lamination including first and second conductivity type nitride semiconductor layers and an active layer formed therebetween;
forming a plurality of patterns in a region of the second conductivity type semiconductor layer, where a second electrode pad will be formed, the plurality of patterns having a depth reaching at least part of the first conductivity type nitride semiconductor layer;
forming an insulating film at an internal surface of the plurality of patterns; and
forming first and second electrode pads electrically connected to the first and second conductivity type nitride semiconductor layers.

12. The method of claim 11, wherein each of the plurality of patterns has inclined side surfaces narrowing with depth.

13. The method of claim 11, further comprising:
mesa etching the light emitting lamination to expose a region of the first conductivity type semiconductor layer, where a first electrode pad will be formed.

14. The method of claim 13, wherein the forming a plurality of patterns is performed simultaneously with the mesa etching.

15. The method of claim 11, further comprising:
forming a transparent electrode layer at an upper surface of the second conductivity type nitride semiconductor layer.

16. The method of claim 11, wherein each of the first and second electrode pads is a single layer or a multilayer that is formed of a material selected from a group consisting of Ti, Cr, Al, Cu, Au, W, and alloys thereof.

17. The method of claim 11, wherein each of the plurality of patterns has a top width of 5 to 50 μm.

18. The method of claim 11, wherein the insulating film is an oxide or a nitride containing an element selected from a group consisting of Si, Zr, Ta, Ti, In, Sn, Mg, and Al.

19. The method of claim 11, further comprising:
forming a high reflective metal layer on the insulating film located at least the plurality of patterns between the forming an insulating film and the forming a second electrode pattern.

20. The method of claim 19, wherein the high reflective metal layer is formed of at least one selected from a group consisting of Al, Ag, Rh, Ru, Pt, Pd, and alloys thereof.
